(19) United States
(12) Patent Application Publication
(10) Pub. No.: US 2026/0150459 A1
(43) Pub. Date: May 28, 2026

(54) DISPLAY DEVICE

(71) Applicant: LG Display Co., Ltd., Seoul (KR)

(72) Inventors: HoJin Ryu, Goyang-si (KR); HeumeIl Baek, Seoul (KR)

(73) Assignee: LG Display Co., Ltd., Seoul (KR)

(21) Appl. No.: 19/313,156

(22) Filed: Aug. 28, 2025

(30) Foreign Application Priority Data
Nov. 26, 2024 (KR) 10-2024-0171299

(51) Int. Cl. H10H 29/37; H10H 29/80; H10H 29/85; H10H 29/851; H10H 29/853; H10H 29/855

(52) U.S. Cl. CPC H10H 29/37; H10H 29/851; H10H 29/8517; H10H 29/853; H10H 29/8552; H10H 29/882

(57) ABSTRACT

A display device includes a first substrate including a plurality of sub pixels, a plurality of light emitting diodes disposed respectively in the plurality of sub pixels on the first substrate, a bank which is disposed so as to expose the plurality of light emitting diodes above the plurality of light emitting diodes and has a hydrophobicity, a plurality of color conversion layers which are disposed respectively on at least two of the plurality of light emitting diodes and are enclosed by the bank, an encapsulation layer which is disposed on the plurality of color conversion layers and is formed of an organic material and a light shielding layer which is disposed in a side portion of the encapsulation layer on the bank. An area of the encapsulation layer is downwardly increased, and an area of the light shielding layer is downwardly reduced.

### CROSS-REFERENCE TO RELATED APPLICATION

This application claims the priority of Korean Patent Application No. 10-2024-0171299, filed on Nov. 26, 2024, in the Korean Intellectual Property Office, the disclosure of which is incorporated herein by reference.

### BACKGROUND

### Field

The present disclosure relates to a display device and, more particularly, to a display device which improves color characteristics.

### Description of the Related Art

Currently, as the world enters a full-scale information era, a field of a display device which visually expresses electrical information signals has been rapidly developed, and studies are continued to improve performances of various display devices, such as a small thickness, a light weight, and low power consumption.

Among various display devices, an organic light emitting display device is a self-emitting display device so that a separate light source is not necessary, which is different from a liquid crystal display device. Therefore, the organic light emitting display device may be manufactured to have a light weight and a small thickness. Further, since the display device is driven at a low voltage, it is advantageous not only in terms of power consumption, but also in terms of color implementation, a response speed, a viewing angle, and a contrast ratio (CR). Therefore, it is expected to be utilized in various fields.

### SUMMARY

An object of the present disclosure is to provide a low-power display device in which color mixture between a plurality of sub pixels is minimized or reduced from being visible to a user to implement a high color reproduction to reduce a power consumption.

Another object of the present disclosure is to provide a display device which minimizes or reduces external light reflection caused as external light entering the display device is reflected.

Still another object of the present disclosure is to provide a display device which places a light shielding layer on a bank in a correct position.

Objects of the present disclosure are not limited to the above-mentioned objects, and other objects, which are not mentioned above, can be clearly understood by those skilled in the art from the following descriptions.

According to an aspect of the present disclosure, a display device includes a first substrate including a plurality of sub pixels; a plurality of light emitting diodes disposed respectively in the plurality of sub pixels on the first substrate; a bank which is disposed so as to expose the plurality of light emitting diodes above the plurality of light emitting diodes and has a hydrophobicity; a plurality of color conversion layers which are disposed respectively on at least two of the plurality of light emitting diodes and are enclosed by the bank; an encapsulation layer which is disposed on the plurality of color conversion layers and is formed of an organic material; and a light shielding layer disposed on the bank and in a side portion of the encapsulation layer. An area of the encapsulation layer is downwardly increased, and an area of the light shielding layer is downwardly reduced.

According to another aspect of the present disclosure, a display device includes: a first substrate in which a plurality of sub pixels including a red sub pixel, a green sub pixel, and a blue sub pixel are defined; a plurality of blue light emitting diodes disposed respectively in the plurality of sub pixels on the first substrate and configured to emit blue light; a bank which is disposed so as to expose the plurality of blue light emitting diodes above the plurality of blue light emitting diodes and has a hydrophobicity; a plurality of color conversion layers which are disposed respectively on blue light emitting diodes in the red sub pixel and the green sub pixel, among the plurality of blue light emitting diodes, and are exposed from the bank; a scattering layer which is disposed on a blue light emitting diode in the blue sub pixel, among the plurality of blue light emitting diodes, and is exposed from the bank; an encapsulation layer which is disposed on the plurality of color conversion layers and the scattering layer exposed from the bank and is formed of an organic material; and a light shielding layer which is disposed on the same layer as the encapsulation layer and is disposed on the bank exposed from the encapsulation layer. In the encapsulation layer, an area of a bottom surface may be larger than an area of a top surface, and in the light shielding layer, an area of a bottom surface may be smaller than an area of a top surface.

Other detailed matters of various example embodiments are included in the detailed description and the drawings.

According to example embodiments of the present disclosure, a black light shielding layer is disposed on a bank to minimize or reduce color mixture between a plurality of sub pixels from being visible to a user.

According to example embodiments of the present disclosure, a black light shielding layer is disposed on a bank to minimize or reduce reflection of external light by the bank.

According to example embodiments of the present disclosure, a bank has a hydrophobicity and an encapsulation layer is not disposed on the bank so that the light shielding layer may be disposed in a correct position on the bank.

The effects according to the present disclosure are not limited to the contents exemplified above, and various additional effects may be attained from the present disclosure.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a plan view of a display device according to an example embodiment of the present disclosure;

FIGS. 2A to 2C are enlarged plan view of an area A of FIG. 1;

FIG. 3 is a cross-sectional view taken along line B-B′ in FIG. 2A;

FIG. 4 is a cross-sectional view taken along line C-C′ in FIG. 2A; and

FIGS. 5A to 5E are process flowcharts for explaining a manufacturing process of a display device according to an example embodiment of the present disclosure.

### DETAILED DESCRIPTION

Advantages and characteristics of the present disclosure and a method of achieving the advantages and characteristics will be clear by referring to example embodiments described below in detail together with the accompanying drawings. However, the present disclosure is not limited to the example embodiments disclosed herein and may be implemented in various other forms. The example embodiments are provided by way of example only so that those skilled in the art can more fully understand the features and aspects of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. Such terms as ‘including’, ‘having’, and ‘consist of’, where used herein, are generally intended to allow other components to be added unless the terms are used with a more limiting term like ‘only’. Any references to singular may include plural unless, and vice versa, expressly stated otherwise.

Components are to be interpreted to include an ordinary error range even if not expressly stated.

Where the position relation between two parts is described using such terms as ‘on’, ‘above’, ‘below’, and ‘next’, one or more parts may be positioned between the two parts unless the terms are used with a more limiting term like ‘immediately’ or ‘directly’.

Where an element or layer is described as being disposed “on” another element or layer, the element or layer may be disposed directly on the other element or layer, or an additional layer or element may be interposed therebetween.

Although the terms “first”, “second”, and the like may be used for describing various components, these components are not confined by these terms. These terms are merely used to refer to one component separately from the other components. Therefore, a first component to be mentioned below may be a second component, and vice versa, in a technical concept of the present disclosure.

Like reference numerals generally denote like elements throughout the specification unless otherwise specified.

A size and a thickness of each component illustrated in the drawing are illustrated for convenience of description, and the present disclosure is not limited to the size and the thickness of the component illustrated.

The features of various example embodiments of the present disclosure can be partially or entirely adhered to or combined with each other and can be interlocked and operated in technically various ways, and the example embodiments can be carried out independently of or in association with each other.

Hereinafter, various example embodiments of the present disclosure will be described in detail with reference to accompanying drawings.

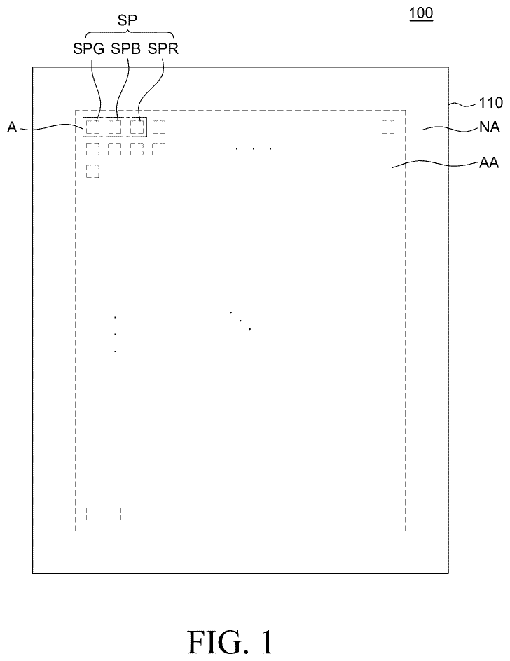

FIG. 1 is a plan view of a display device according to an example embodiment of the present disclosure. In FIG. 1, for the convenience of description, among various components of the display device 100, only a first substrate 110 and a plurality of sub pixels SP are illustrated.

The first substrate 110 is a component for supporting various components included in the display device 100 and may be formed of an insulating material. For example, the first substrate 110 may be formed of glass or resin. Further, the first substrate 110 may be configured to include polymer or plastics or may be formed of a material having flexibility, but is not limited thereto.

The first substrate 110 includes an active area AA and a non-active area NA.

The active area AA is an area where a plurality of sub pixels SP is disposed to display images. In each of the plurality of sub pixels SP of the active area AA, a display element and a driving circuit for driving the display element may be disposed. For example, in each of the plurality of sub pixels SP, a light emitting diode, such as LED, which is a display element and a transistor which is a driving element for driving the LED may be disposed.

The non-active area NA is an area where no image is displayed and various wiring lines and driving ICs for driving the sub pixels SP disposed in the active area AA are disposed. For example, in the non-active area NA, various ICs such as a gate driver IC and a data driver IC and driving circuits may be disposed.

A plurality of sub pixels SP is disposed in the active area AA. The plurality of sub pixels SP may be defined in the active area AA of the first substrate 110. Each of the plurality of sub pixels SP is an individual unit which emits light and in each of the plurality of sub pixels SP, a light emitting diode and a driving element may be disposed. The light emitting diode may be defined in different manners depending on the type of the display panel. For example, when the display panel is an inorganic light emitting display panel, the light emitting diode may be a light emitting diode (LED) or a micro light emitting diode (micro LED), but is not limited thereto. The driving circuit for driving the plurality of sub pixels SP may include a driving element such as a thin film transistor and a wiring line. For example, the driving circuit may be configured by a thin film transistor, a storage capacitor, a gate line, and a data line, but is not limited thereto.

For example, the plurality of sub pixels SP may include a red sub pixel SPR, a green sub pixel SPG, and a blue sub pixel SPB. In the meantime, the plurality of sub pixels SP may further include a white sub pixel, but is not limited thereto. However, in the following description, for the convenience of description, it is assumed that the plurality of sub pixels SP includes a red sub pixel SPR, a green sub pixel SPG, and a blue sub pixel SPB.

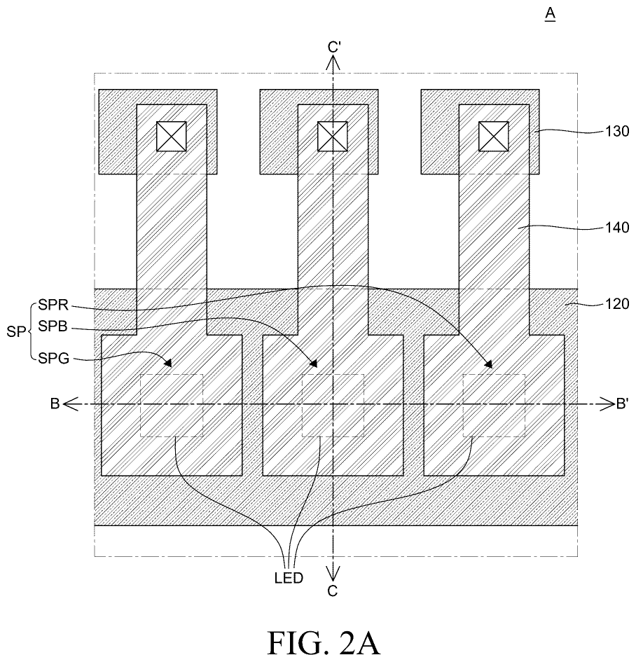

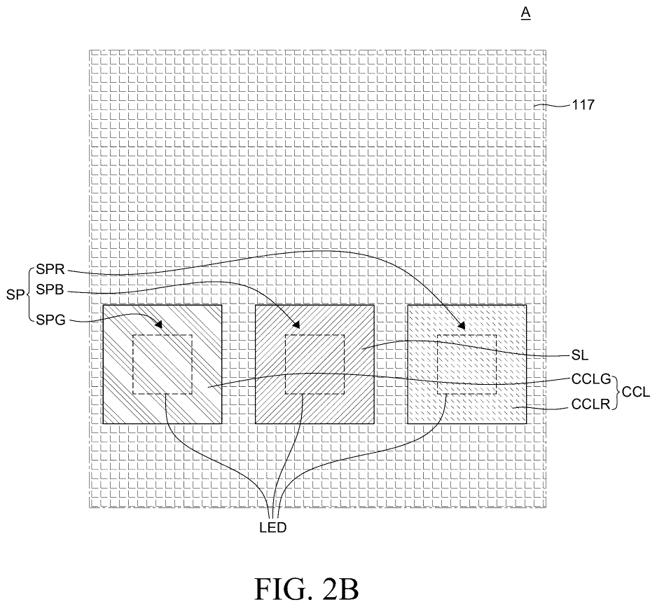

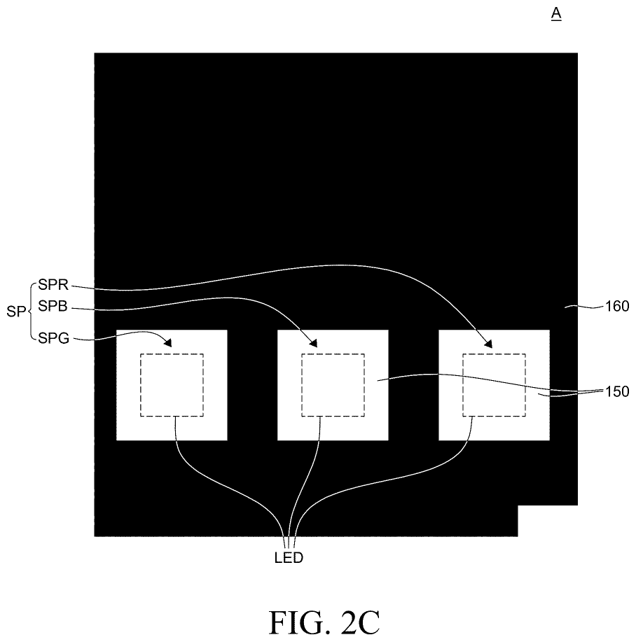

Hereinafter, the active area AA of the display device 100 will be described in more detail with reference to FIGS. 2A to 4 together.

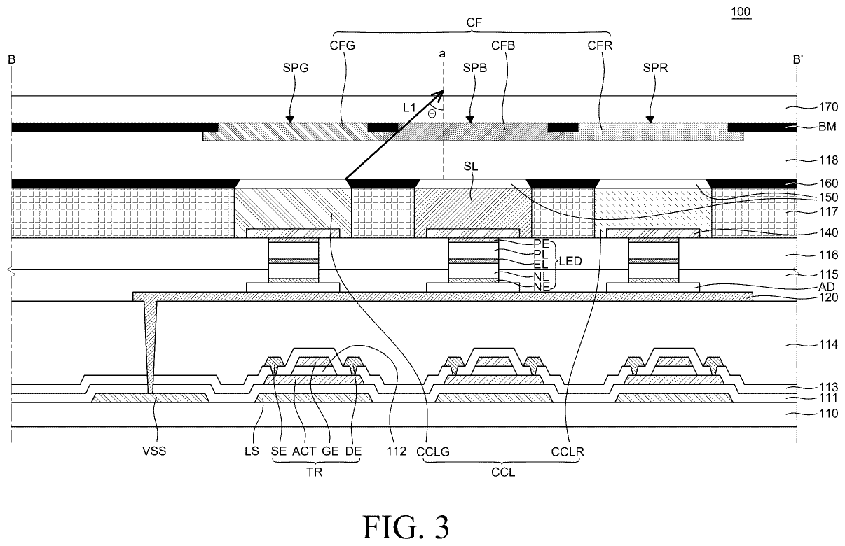

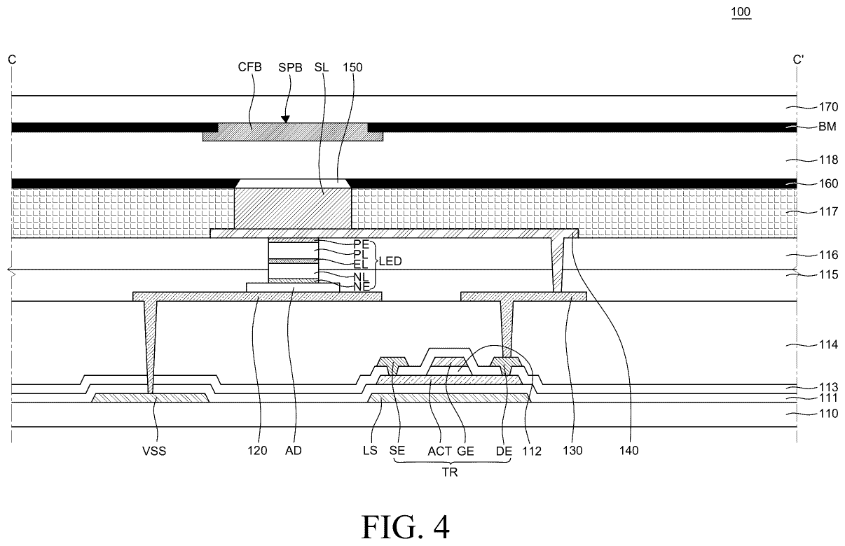

FIGS. 2A to 2C are enlarged plan views of an area A of FIG. 1. FIG. 3 is a cross-sectional view taken along line B-B′ in FIG. 2A. FIG. 4 is a cross-sectional view taken along line C-C′ in FIG. 2A. FIGS. 2A to 2C are enlarged plan views illustrating different layers for the area A of FIG. 1 which is the same area. In the meantime, for the convenience of illustration, in FIG. 2A, among various components of the display device 100, only a first reflection electrode 120, a second reflection electrode 130, a plurality of light emitting diodes LED, and a connection electrode 140 are illustrated. Further, in FIG. 2B, among various components of the display device 100, only a plurality of light emitting diodes LED, a bank 117, a color conversion layer CCL, and a scattering layer SL are illustrated. The plurality of color conversion layers CCL may include a green color conversion layer CCLG and a red color conversion layer CCLR. In FIG. 2C, among various components of the display device 100, only a plurality of light emitting diodes LED, an encapsulation layer 150, and a light shielding layer 160 are illustrated.

As shown in FIGS. 2A to 4, the display device 100 according to the example embodiment of the present disclosure includes a first substrate 110, a plurality of protection layers LS, a power line VSS, a buffer layer 111, a gate insulating layer 112, an interlayer insulating layer 113, a plurality of transistors TR, a first planarization layer 114, a first reflection electrode 120, a second reflection electrode 130, a conductive adhesive layer AD, a plurality of light emitting diodes LED, a second planarization layer 115, a third planarization layer 116, a connection electrode 140, a bank 117, a plurality of color conversion layers CCL, a plurality of scattering layers SL, an encapsulation layer 150, a light shielding layer 160, an adhesive layer 118, a color filter CF, a black matrix BM, and a second substrate 170.

First, the first substrate 110 is a component for supporting various components included in the display device 100 and may be formed of an insulating material. For example, the first substrate 110 may be formed of glass or resin. Further, the first substrate 110 may be configured to include polymer or plastics or may be formed of a material having flexibility, but is not limited thereto.

The protection layer LS and the power line VSS are disposed on the first substrate 110.

The protection layer LS is disposed in each of the plurality of sub pixels SP on the first substrate 110. The protection layer LS is disposed in each of the plurality of transistors TR disposed in each of the plurality of sub pixels SP. The protection layer LS blocks light incident to an active layer ACT of the transistor TR, below the transistor TR. The protection layer LS blocks light which is incident to the active layer ACT of the transistor TR to protect the active layer ACT so as not to be damaged by the light. Therefore, the protection layer LS may serve as a light shielding layer, but is not limited thereto.

The power line VSS is disposed to be adjacent to the plurality of transistors TR on the first substrate 110. The power line VSS is spaced apart from the protection layer LS on the same layer and may be formed of the same material as the protection layer LS. The power line VSS may be configured by a conductive material, such as copper (Cu), aluminum (Al), molybdenum (Mo), nickel (Ni), titanium (Ti), chrome (Cr), or an alloy thereof, but is not limited thereto.

As shown in FIGS. 3 and 4, the power line VSS is electrically connected to the first reflection electrode 120. A low potential voltage may be supplied to the power line VSS. The power line VSS is electrically connected to the light emitting diode LED together with the transistor TR to allow the light emitting diode LED to emit light. For example, the power line VSS may be connected to an n-type electrode of the light emitting diode LED through the first reflection electrode 120. Therefore, the power line VSS may supply a low potential voltage to the n-type electrode of the light emitting diode LED. However, the power line VSS is not limited thereto and may be a high potential power line which supplies a high potential voltage.

The buffer layer 111 is disposed on the first substrate 110, the protection layer LS, and the power line VSS. The buffer layer 111 may reduce permeation of moisture or impurities through the first substrate 110. The buffer layer 111 may be configured by a single layer or a double layer of silicon oxide (SiOx) or silicon nitride (SiNx), but is not limited thereto. However, the buffer layer 111 may be omitted depending on a type of first substrate 110 or a type of transistor, but is not limited thereto.

The transistor TR is disposed on the buffer layer 111. The transistor TR includes an active layer ACT, a gate electrode GE, a source electrode SE, and a drain electrode DE.

The active layer ACT is disposed on the buffer layer 111. For example, the active layer ACT may be formed of a semiconductor material, such as an oxide semiconductor, amorphous silicon, or polysilicon, but is not limited thereto.

The gate insulating layer 112 is disposed on the buffer layer 111 and the active layer ACT. The gate insulating layer 112 is a layer for insulating the active layer ACT from the gate electrode GE. For example, the gate insulating layer 112 may be configured by a single layer or a double layer of silicon oxide (SiOx) or silicon nitride (SiNx), but is not limited thereto.

In the meantime, the gate insulating layer 112, as illustrated in FIGS. 3 and 4, may be disposed only in an area which overlaps the gate electrode GE, but may be disposed in the entire area of the first substrate 110 according to the design, but is not limited thereto.

The gate electrode GE is disposed on the gate insulating layer 112. The gate electrode GE may be configured by a conductive material, such as copper (Cu), aluminum (Al), molybdenum (Mo), nickel (Ni), titanium (Ti), chrome (Cr), or an alloy thereof, but is not limited thereto.

The interlayer insulating layer 113 is disposed on the gate electrode GE. In the interlayer insulating layer 113, a contact hole through which the source electrode SE and the drain electrode DE is connected to the active layer ACT is formed. The interlayer insulating layer 113 is an insulating layer which protects components below the interlayer insulating layer 113 and may be configured by a single layer or a double layer of silicon oxide (SiOx) or silicon nitride (SiNx), but is not limited thereto.

The source electrode SE and the drain electrode DE are disposed on the interlayer insulating layer 113. The source electrode SE and the drain electrode SE may be electrically connected to the active layer ACT through a contact hole of the interlayer insulating layer 113. The source electrode SE and the drain electrode DE may be configured by a conductive material, such as copper (Cu), aluminum (Al), molybdenum (Mo), nickel (Ni), titanium (Ti), chrome (Cr), or an alloy thereof, but are not limited thereto.

The first planarization layer 114 is disposed on the transistor TR. The first planarization layer 114 may planarize an upper portion of the first substrate 110 on which the transistor TR is disposed. The first planarization layer 114 may be configured by a single layer or a double layer, and for example, may be formed of photoresist or an acrylic organic material, but is not limited thereto.

A plurality of reflection electrodes 120 and 130 which is spaced apart from each other is disposed on the first planarization layer 114. The plurality of reflection electrodes 120 and 130 may electrically connect the light emitting diode LED to the power line VSS and the transistor TR and serve as a reflector which reflects light emitted from the light emitting diode LED to the upper portion of the light emitting diode LED. The plurality of reflection electrodes 120 and 130 is formed of a conductive material having the excellent reflecting property to reflect light emitted from the light emitting diode LED toward the top of the light emitting diode LED.

The plurality of reflection electrodes 120 and 130 includes a first reflection electrode 120 and a second reflection electrode 130.

The first reflection electrode 120 may electrically connect the power line VSS and the light emitting diode LED. The first reflection electrode 120 may be connected to the power line VSS through a contact hole formed in the first planarization layer 114 and may be electrically connected to an n-type electrode NE of the light emitting diode LED through a connection electrode 140.

The second reflection electrode 130 may electrically connect the transistor TR and the light emitting diode LED. The second reflection electrode 130 may be connected to the source electrode SE or the drain electrode DE of the transistor TR through a contact hole formed in the first planarization layer 114.

A conductive adhesive layer AD is disposed on the first reflection electrode 120. The conductive adhesive layer AD is formed on the first reflection electrode 120 to fix the light emitting diode LED disposed on the conductive adhesive layer AD. Further, the conductive adhesive layer AD may electrically connect the first reflection electrode 120 and the plurality of light emitting diodes LED. Specifically, the conductive adhesive layer AD may fix and electrically connect the first reflection electrodes 120 disposed therebelow and the n-type electrode NE of the light emitting diode LED disposed thereabove.

The conductive adhesive layer AD may be formed of a conductive adhesive material. For example, the conductive adhesive layer AD may include a conductive black material. Therefore, the conductive adhesive layer AD may be black. For example, the conductive black material may include carbon. For example, the conductive adhesive layer AD may be formed by dispersing a conductive black material including carbon in an acrylic resin, but is not limited thereto.

The plurality of light emitting diode s LED is disposed in each of the plurality of sub pixels SP on the conductive adhesive layer AD. The plurality of light emitting diodes LED is elements which emit light by a current and may include a light emitting diode LED which emits blue light. For example, all the plurality of light emitting diodes LED disposed in the plurality of sub pixels SP may be blue light emitting diodes which emit blue light, but is not limited thereto. For example, the plurality of light emitting diodes LED may be light emitting diodes (LED) or micro LEDs, but is not limited thereto.

The light emitting diode LED includes an n-type electrode NE, an n-type layer NL, an emission layer EL, a p-type layer PL, and a p-type electrode PE.

The n-type electrode NE is disposed on the conductive adhesive layer AD. The n-type electrode NE is an electrode which electrically connects the transistor TR and the n-type layer NL. In this case, the n-type layer NL may be a semiconductor doped with an n-type impurity and the n-type electrode NE may be a cathode. The n-type electrode NE may be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

The n-type layer NL is disposed on the n-type electrode NE. The n-type layer NL may be a layer formed by doping an n-type impurity into a specific material. For example, the n-type layer NL may be a layer formed by doping an n-type impurity into a material, such as gallium nitride (GaN), indium aluminum phosphide (InAlP), or gallium arsenide (GaAs). At this time, the n-type impurity may be silicon (Si), germanium, or tin (Sn), but is not limited thereto.

The emission layer EL is disposed on the n-type layer NL. The emission layer EL is disposed between the n-type layer NL and the p-type layer PL. The emission layer EL is supplied with holes and electrons from the n-type layer NL and the p-type layer PL to emit light. The emission layer EL may be formed by a single layer or a multi-quantum well (MQW) structure, and for example, may be formed of indium gallium nitride (InGaN) or gallium nitride (GaN), but is not limited thereto.

The p-type layer PL is disposed on the emission layer EL. The p-type layer PL may be a layer formed by doping a p-type impurity into a specific material. For example, the p-type layer PL may be a layer formed by doping a p-type impurity into a material, such as gallium nitride (GaN), indium aluminum phosphide (InAlP), or gallium arsenide (GaAs). The p-type impurity may be magnesium, zinc (Zn), or beryllium (Be), but is not limited thereto. The p-type electrode PE is disposed on the p-type layer PL. The p-type electrode PE may be disposed on a top surface of the p-type layer PL. The p-type electrode PE is an electrode which electrically connects the power line VSS and the p-type layer PL. In this case, the p-type layer PL may be a semiconductor layer doped with a p-type impurity and the p-type electrode PE may be an anode. The p-type electrode PE may be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

The second planarization layer 115 and the third planarization layer 116 are disposed on the first planarization layer 114, the first reflection electrode 120, and the second reflection electrode 130. The second planarization layer 115 is disposed so as to enclose a part of a side surface below the plurality of light emitting diodes LED and the third planarization layer 116 is disposed so as to enclose a part of a side surface above the plurality of light emitting diodes LED to planarize upper portions of the plurality of light emitting diodes LED. Therefore, the second planarization layer 115 and the third planarization layer 116 may fix and protect the plurality of light emitting diodes LED.

For example, the second planarization layer 115 and the third planarization layer 116 may be configured by a single layer or a double layer, and for example, may be formed of photoresist or an acrylic organic material, but are not limited thereto.

The connection electrode 140 may be disposed on the third planarization layer 116. The connection electrode 140 is an electrode which is disposed in each of the plurality of sub pixels SP to electrically connect the light emitting diode LED and the transistor TR. The connection electrode 140 may be connected to the second reflection electrode 130 through the contact holes formed in the second planarization layer 115 and the third planarization layer 116. Accordingly, the connection electrode 140 may be electrically connected to the power line VSS through the second reflection electrode 130. Further, the connection electrode 140 is disposed on the p-type electrode PE of the light emitting diode LED exposed from the third planarization layer 116 to be connected to the p-type electrode PE of the light emitting diode LED.

The bank 117, the plurality of color conversion layers CCL, and the scattering layer SL are disposed on the third planarization layer 116 and the connection electrode 140.

The bank 117 is disposed on the third planarization layer 116 and the connection electrode 140. The bank 117 is disposed between the plurality of sub pixels SP to minimize or suppress color mixture caused by light which is emitted from the plurality of sub pixels SP to travel to another sub pixel SP. The bank 117 may be disposed along a boundary between the plurality of sub pixels SP. At this time, as shown in FIGS. 2B, 3, and 4, the bank 117 may be disposed on the third planarization layer 116 and the connection electrode 140 to expose the plurality of light emitting diodes LED (e.g. a plurality of blue light emitting diodes). That is, the bank 117 may be disposed only in an area which does not overlap the light emitting diode LED, above the light emitting diode LED, but is not limited thereto.

The bank 117 may have hydrophobicity. Further, the bank 117 may include a transparent or white material. For example, the bank 117 may be formed of an organic insulating layer or an inorganic insulating layer to which a hydrophobic material and a white material are added, but is not limited thereto.

The plurality of color conversion layers CCL and the scattering layer SL are disposed on the plurality of light emitting diodes LED. The plurality of color conversion layers CCL and the scattering layer SL may be disposed on the same layer on the plurality of light emitting diodes LED. As shown in FIGS. 2B, 3, and 4, the plurality of color conversion layers CCL and the scattering layer SL are disposed on the plurality of light emitting diodes LED exposed from the bank 117. That is, the plurality of color conversion layers CCL and the scattering layer SL may be disposed to correspond to the plurality of sub pixels SP to be filled in a space between the banks 117. The plurality of color conversion layers CCL and the scattering layer SL are disposed on the same layer as the bank 117 to be enclosed by the bank 117. That is, side surfaces of the plurality of color conversion layers CCL and a side surface of the scattering layer SL may be in contact with a side surface of the bank 117.

The plurality of color conversion layers CCL may be disposed so as to correspond to a green sub pixel SPG and a red sub pixel SPR, among the plurality of sub pixels SP. The plurality of color conversion layers CCL absorbs light to emit light having a different wavelength. The plurality of color conversion layers CCL may convert blue light emitted from the plurality of light emitting diodes LED which is blue light emitting diodes and emit it as green light or red light. The plurality of color conversion layers CCL may include a green color conversion layer CCLG and a red color conversion layer CCLR. The green color conversion layer CCLG and the red color conversion layer CCLR may include different color conversion materials, respectively.

The green color conversion layer CCLG is disposed to correspond to the green sub pixel SPG, among the plurality of sub pixels SP. Blue light emitted from the light emitting diode LED may be converted into green light while passing through the green color conversion layer CCLG. The green color conversion layer CCLG may convert light having a wavelength of approximately 400 nm or higher and 480 nm or lower into light having a wavelength of approximately 520 nm or higher and 580 nm or lower, but is not limited thereto.

The red color conversion layer CCLR is disposed to correspond to the red sub pixel SPR, among the plurality of sub pixels SP. Blue light emitted from the light emitting diode LED may be converted into red light while passing through the red color conversion layer CCLR. The red color conversion layer CCLR may convert light having a wavelength of approximately 400 nm or higher and 480 nm or lower into light having a wavelength of approximately 600 nm or higher and 640 nm or lower, but is not limited thereto.

For example, the plurality of color conversion layers CCL may include photoluminescent material which absorbs first color light, that is, light having a first wavelength to emit second color light, that is, light having a second wavelength. For example, the plurality of color conversion layers may include a nano fluorescent material, an organic fluorescent material, or a quantum dot, but is not limited thereto.

The scattering layer SL is disposed to correspond to the blue sub pixel SPB, among the plurality of sub pixels SP. For example, when the light emitting diode LED is a blue light emitting diode which emits blue light, the blue sub pixel SPB may be configured to transmit the blue light without placing the color conversion layer CCL. For example, the scattering layer SL may be formed of a transparent material which transmits blue light. In the meantime, the scattering layer SL may include a plurality of particles having a property of scattering light. Therefore, the scattering layer SL may be configured to control the property of light emitted from the blue sub pixel SPB, but is not limited thereto.

The encapsulation layer 150 and the light shielding layer 160 are disposed on the bank 117, the color conversion layer CCL, and the scattering layer SL.

The encapsulation layer 150 is disposed on the color conversion layer CCL and the scattering layer SL. The encapsulation layer 150 protects configurations below the encapsulation layer 150 from moisture, air, or physical impact which may permeate from the outside. The encapsulation layer 150 is disposed so as to overlap the plurality of light emitting diodes LED, the color conversion layer CCL, the scattering layer SL, and the color filter CF. The encapsulation layer 150 is disposed so as to overlap only onto the color conversion layer CCL and the scattering layer SL among the bank 117, the color conversion layer CCL, and the scattering layer SL. Specifically, the encapsulation layer 150 is disposed so as to overlap only the color conversion layer CCL, between the color conversion layer CCL and the bank 117. That is, the encapsulation layer 150 is disposed so as not to overlap the bank 117 and is not disposed on the bank 117.

An area of a bottom surface of the encapsulation layer 150 may be configured to be larger than an area of a top surface. The encapsulation layer 150 may be configured such that an area of a cross section of the encapsulation layer 50 is increased downwardly (toward the bottom). The encapsulation layer 150 may be configured such that a width of the lower portion is larger than a width of the upper portion on the cross section. For example, as illustrated in FIGS. 3 and 4, a cross-sectional shape of the encapsulation layer 150 may be a tapered shape. However, the cross-sectional shape of the encapsulation layer 150 may include a curved line, but is not limited thereto.

The encapsulation layer 150 may be formed by a single layer including an organic material. Further, the encapsulation layer 150 may have a hydrophilicity. For example, the encapsulation layer 150 may be formed of an acrylic organic material having the hydrophilicity, but is not limited thereto. In the meantime, the encapsulation layer 150 has a hydrophilicity so that when the encapsulation layer 150 is formed, the encapsulation layer may be configured so as not to be disposed on the bank 117 having the hydrophobicity.

The light shielding layer 160 is disposed on the bank 117. The light shielding layer 160 may be disposed so as to overlap the bank 117 and the black matrix BM. The light shielding layer 160 may be disposed on the same layer as the encapsulation layer 150 and disposed in a side portion of the encapsulation layer 150. The light shielding layer 160 may be disposed on the bank 117 exposed from the encapsulation layer 150.

The side surface of the light shielding layer 160 is in contact with the encapsulation layer 150 and may have a shape corresponding to the encapsulation layer 150. An area of a top surface of the light shielding layer 160 may be configured to be larger than an area of a bottom surface. The light shielding layer 160 may be configured such that an area of a cross-section of the light shielding layer 160 is reduced downwardly (toward the bottom). The light shielding layer 160 may be configured such that a width of the lower portion is smaller than a width of the upper portion on the cross section. For example, as illustrated in FIGS. 3 and 4, a cross-sectional shape of the light shielding layer 160 may be a reverse tapered shape. However, the cross-sectional shape of the light shielding layer 160 may include a curved line, but is not limited thereto. The light shielding layer 160 may have the same height as the encapsulation layer 150.

For example, the light shielding layer 160 may include a black material which absorbs light without transmitting the light. At this time, the black material may include an organic material or an inorganic material. The black material may include a carbon-based material or metal oxide, but is not limited thereto.

The adhesive layer 118 is disposed on the encapsulation layer 150 and the light shielding layer 160. The adhesive layer 118 is a layer for bonding the first substrate 110 and the second substrate 170. Specifically, the adhesive layer 118 may be used to bond the first substrate 110 on which the encapsulation layer 150 and the light shielding layer 160 are formed and the second substrate 170 on which the color filter CF and the black matrix BM are formed. For example, the adhesive layer 118 may be formed of a transparent photo-curable adhesive material, but is not limited thereto.

The plurality of color filters CF is disposed on the adhesive layer 118. The plurality of color filters CF is disposed so as to correspond to the plurality of sub pixels SP, that is, the plurality of color conversion layers CCL and the scattering layer SL.

The plurality of color filters CF may filter different color light. For example, the green color filter CFG disposed in the green sub pixel SPG may filter light other than the green light and release green light and the blue color filter CFB disposed in the blue sub pixel SPB may filter light other than the blue light and release blue light. The red color filter CFR disposed in the red sub pixel SPR may filter light other than the red light and release red light.

The black matrix BM is disposed on the plurality of color filters CF. The black matrix BM is disposed between the plurality of color filters CF to reduce color mixture between the plurality of sub pixels SP

In the meantime, as shown in FIGS. 3 and 4, the black matrix BM overlaps the light shielding layer 160 and is disposed in a narrower area than the light shielding layer 160. That is, the size of the black matrix BM may be smaller than a size of the light shielding layer 160. Therefore, the black matrix BM may be configured to minimize or suppress the restriction of the viewing angle of light emitted from the light emitting diode LED.

The black matrix BM may include a black material which absorbs light without transmitting the light. At this time, the black material may include an organic material or an inorganic material. For example, the black material may include a carbon-based material or metal oxide, but is not limited thereto.

The second substrate 170 is disposed on the color filter CF and the black matrix BM. The second substrate 170 is a substrate which supports various components disposed below the second substrate 170. Specifically, the second substrate 170 may support the plurality of color filters CF and the black matrix BM disposed therebelow. The second substrate 170 may be formed of the same material as the first substrate 110, for example, may be formed of glass or resin, but is not limited thereto.

In the meantime, as shown in FIG. 3, when a virtual reference line for a location where a center viewing angle of the sub pixel SP, that is, a viewing angle in the front of the display device 100 is 0° is “a” and among light emitted from a light emitting diode LED of one sub pixel SP, light which is output to the other adjacent sub pixel SP is first light L1, as an angle θ formed by the reference line “a” and the first light L1 is increased, the first light L1 is output at a lower viewing angle from the display device 100 so that the visibility for the first light L1 may be reduced. That is, as among light emitted from one sub pixel SP, first light L1 output to the other adjacent sub pixel SP is output at a lower viewing angle, the visibility may be reduced. Accordingly, the color mixture between adjacent sub pixels SP may also be minimized or suppressed.

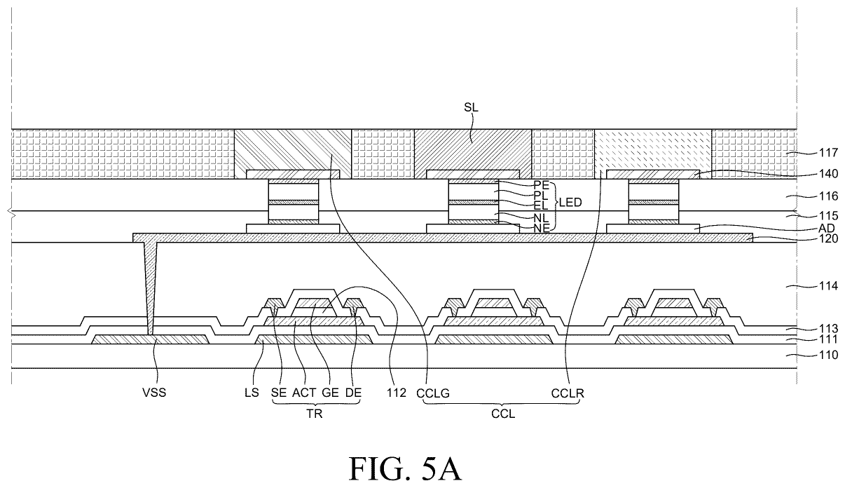

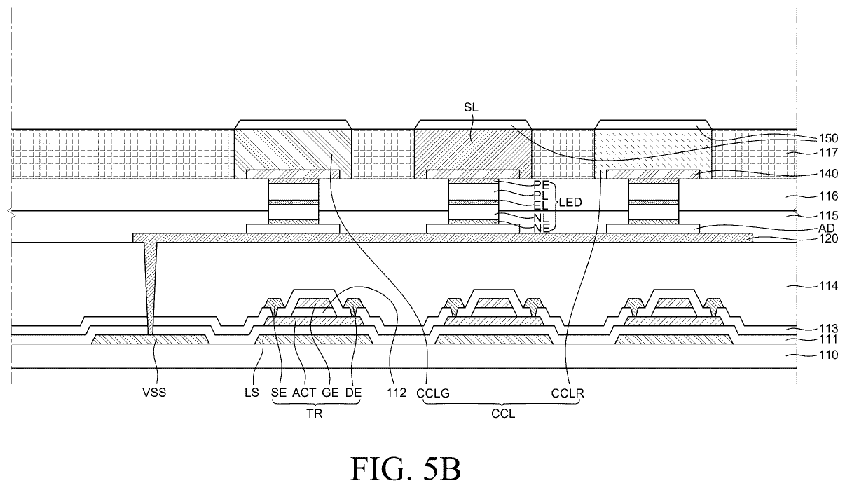

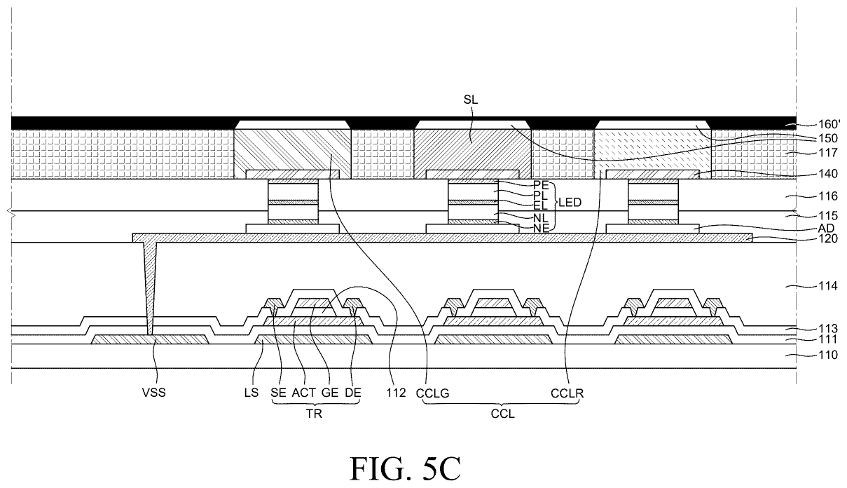

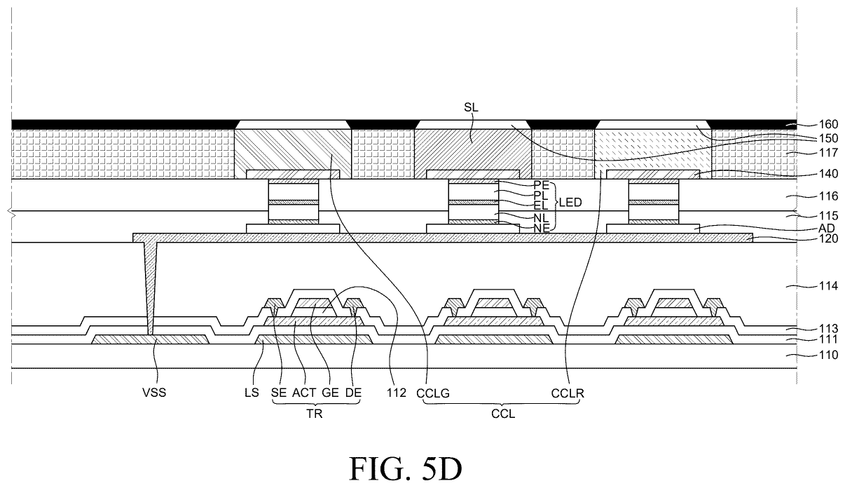

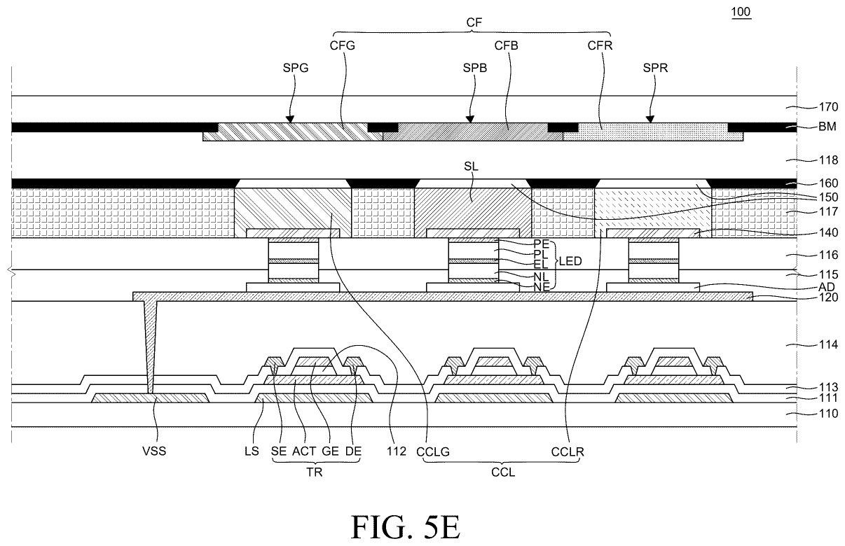

Hereinafter, a manufacturing process of a display device 100 according to an example embodiment of the present disclosure will be described with reference to FIGS. 5A to 5E.

FIGS. 5A to 5E are process flowcharts for explaining a manufacturing process of a display device according to an example embodiment of the present disclosure.

First, as shown in FIG. 5A, a plurality of transistors TR and a plurality of light emitting diodes LED are formed on the first substrate 110. The bank 117 is formed so as to expose the plurality of light emitting diodes LED. At this time, the bank 117 includes a white material and may have hydrophobicity. Next, a color conversion layer CCL and a scattering layer SL are formed in a space exposed from the bank 117, that is, above the plurality of light emitting diodes LED. At this time, a method of forming the color conversion layer CCL and the scattering layer SL may be configured by a process of placing materials for forming the color conversion layer CCL and the scattering layer SL in a space exposed from the bank 117 by an inkjet method, but is not limited thereto.

Next, as shown in FIG. 5B, an encapsulation layer 150 is formed on the color conversion layer CCL and the scattering layer SL. For example, the encapsulation layer 150 may be formed using the inkjet method, but is not limited thereto. At this time, the encapsulation layer 150 may have a hydrophilicity. Therefore, the encapsulation layer 150 may be configured so as not to be disposed on the bank 117 having the hydrophobicity. That is, the encapsulation layer 150 may be disposed only in a part which does not overlap the bank 117.

Next, as shown in FIG. 5C, a material 160′ for forming the light shielding layer 160 is patterned on the bank 117 and the encapsulation layer 150. In the meantime, the material 160′ for forming the light shielding layer 160 is patterned so as to expose a plurality of pads disposed in the non-active area NA, but is not limited thereto.

Next, as shown in FIG. 5D, a top surface of the material 160′ for forming the light shielding layer 160 is removed by ashing the material 160′ for forming the light shielding layer 160 to expose the encapsulation layer 150 from the light shielding layer 160. Therefore, the light shielding layer 160 may be aligned in a correct position which does not overlap the color conversion layer CCL and the scattering layer SL below the encapsulation layer 150 on the bank 117.

Finally, as shown in FIG. 5E, the adhesive layer 118, the color filter CF, the black matrix BM, and the second substrate 170 are formed on the encapsulation layer 150 and the light shielding layer 160 to complete the manufacturing process of the display device 100. At this time, the first substrate 110 on which the encapsulation layer 150 and the light shielding layer 160 are formed and the second substrate 170 on which the color filter CF and the black matrix BM are formed are bonded by the adhesive layer 118. By doing this, a process of forming the adhesive layer 118, the color filter CF, the black matrix BM, and the second substrate 170 on the encapsulation layer 150 and the light shielding layer 160 may be performed. However, the present disclosure is not limited thereto.

In a display device including a color conversion layer which converts a color of light emitted from the light emitting diode and a bank which encloses the color conversion layer, the bank is configured to include a black material or a white material to reduce color mixture of sub pixels which emit different color light.

However, a bank including a black material absorbs a part of light emitted from the light emitting diode so that the light extraction efficiency of the display device may be degraded. Further, light emitted from the light emitting diode passes through a bank including a white material to be output through a color filter of the other adjacent sub pixel to cause color mixture between adjacent sub pixels.

At this time, light which passes through the bank including the white material may be output from a height adjacent to the light emitting diode so that as compared with an example that light is blocked by the bank including a black material, the light may be output at a higher viewing angle in the front of the display device. Therefore, in the bank including the white material, the color mixture between the adjacent sub pixels may be more serious due to the light which passes through the bank.

In the display device 100 according to the example embodiment of the present disclosure, the light shielding layer 160 including the black material is disposed on the bank 117 including the white material to improve the light extraction efficiency and minimize or suppress the color mixture between adjacent sub pixels SP.

Specifically, in the display device 100 according to the example embodiment of the present disclosure, the light shielding layer 160 including the black material may be further disposed on the bank 117 including the white material. Accordingly, the bank 117 including the white material is disposed in an upper portion adjacent to the light emitting diode LED so that the light emitted from the light emitting diode LED is reflected by the bank 117 to improve the light extraction efficiency of the display device 100. At this time, as the light shielding layer 160 is disposed on the bank 117, a height at which light emitted from the light emitting diode LED is emitted between the light shielding layers 160 may be increased. Accordingly, as illustrated in FIG. 3, an angle θ formed by first light L1 which is output between the light shielding layer 160 to be output to the other adjacent sub pixel SP, among light emitted from the light emitting diode LED, and a reference line “a” may be increased. That is, in the display device 100 according to the example embodiment of the present disclosure, as compared with an example that the light shielding layer 160 is not disposed, a height at which light emitted from the light emitting diode LED is output between the light shielding layers 160 may be further increased. Further, an angle formed by first light L1 which is output between the light shielding layer 160 to be output to the other adjacent sub pixel SP and the reference line “a” may be further increased. Therefore, among light emitted from one sub pixel SP, first light L1 which is output to the other adjacent sub pixel SP may be output at a lower angle than in the example that the light shielding layer 160 is not disposed and the color mixture of the adjacent sub pixels SP may be minimized or suppressed. Accordingly, in the display device 100 according to the example embodiment of the present disclosure, the light shielding layer 160 including the black material is disposed on the bank 117 including the white material to improve the light extraction efficiency and minimize or suppress the color mixture between adjacent sub pixels SP. Further, a display quality of the display device 100 may be improved.

Further, in the display device 100 according to the example embodiment of the present disclosure, the light shielding layer 160 including the black material is disposed on the bank 117 including the white material to minimize or reduce light which is incident from the upper portion of the bank 117 from being reflected by the bank 117. Accordingly, the light shielding layer 160 is disposed on the bank 117 to minimize or reduce the external light reflection that external light incident from the outside of the display device 100 is reflected by the bank 117 which includes a white material and has an improved reflectivity.

In the meantime, in the display device 100 according to the example embodiment of the present disclosure, the bank 117 is configured to have the hydrophobicity to place the light shielding layer 160 in the correct position on the bank.

Specifically, in the display device 100 according to the example embodiment of the present disclosure, the bank 117 is configured to have the hydrophobicity and the encapsulation layer 150 is configured to have the hydrophilicity. Accordingly, the encapsulation layer 150 may not be disposed on the bank 117 having the hydrophobicity. That is, the encapsulation layer 150 may be disposed only in a part which does not overlap the bank 117. The light shielding layer 160 is formed on the bank 117 in which the encapsulation layer 150 is not disposed so that the light shielding layer 160 may be disposed in the correct position on the bank 117. Accordingly, in the display device 100 according to the example embodiment of the present disclosure, the bank 117 is configured to have the hydrophobicity to place the light shielding layer 160 in the correct position on the bank.

Various example embodiments of the present disclosure can also be described as follows:

According to an aspect of the present disclosure, a display device may include a first substrate including a plurality of sub pixels; a plurality of light emitting diodes disposed respectively in the plurality of sub pixels on the first substrate; a bank which is disposed so as to expose the plurality of light emitting diodes above the plurality of light emitting diodes and has a hydrophobicity; a plurality of color conversion layers which are disposed on at least two of the plurality of light emitting diodes and are enclosed by the bank; an encapsulation layer which is disposed on the plurality of color conversion layers and is formed of an organic material; and a light shielding layer disposed on the bank and in a side portion of the encapsulation layer. An area of the encapsulation layer is downwardly increased, and an area of the light shielding layer is downwardly reduced.

According to some embodiments of the display device, a cross-sectional shape of the encapsulation layer may be a tapered shape, and a cross-sectional shape of the light shielding layer may be a reverse tapered shape.

According to some embodiments, the encapsulation layer may be disposed so as to overlap only the plurality of color conversion layers, among the plurality of color conversion layers and the bank.

According to some embodiments, the encapsulation layer may be hydrophilic.

According to some embodiments, the bank may include a white material, and the light shielding layer may include a black material.

According to some embodiments, the display device may further comprise a scattering layer which is disposed on the same layer as the plurality of color conversion layers on one of the plurality of light emitting diodes other than the at least two of the plurality of light emitting diodes.

According to some embodiments, the plurality of light emitting diodes may be blue light emitting diodes which emit blue light, and the plurality of sub pixels may include a red sub pixel, a green sub pixel, and a blue sub pixel. The plurality of color conversion layers may be disposed so as to correspond to the red sub pixel and the green sub pixel, among the plurality of sub pixels, and the scattering layer may be disposed so as to correspond to the blue sub pixel, among the plurality of sub pixels.

According to some embodiments, the display device may further comprise a plurality of color filters which is disposed so as to correspond to the plurality of color conversion layers under the encapsulation layer; a black matrix which is disposed between the plurality of color filters on the plurality of color filters; and a second substrate disposed on the plurality of color filters and the black matrix.

According to some embodiments, the at least two of the plurality of light emitting diodes may be disposed so as to overlap the plurality of color conversion layers, respectively, the encapsulation layer, and the plurality of color filters, respectively, and the bank may be disposed so as to overlap the light shielding layer and the black matrix.

According to some embodiments, the light shielding layer and the black matrix may be disposed so as to overlap each other, and the black matrix may be disposed in an area narrower than the light shielding layer.

According to another aspect of the present disclosure, a display device may include a first substrate in which a plurality of sub pixels including a red sub pixel, a green sub pixel, and a blue sub pixel is defined; a plurality of blue light emitting diodes disposed respectively in the plurality of sub pixels on the first substrate and emits blue light; a bank which is disposed so as to expose the plurality of blue light emitting diodes above the plurality of blue light emitting diodes and has a hydrophobicity; a plurality of color conversion layers which are disposed respectively on blue light emitting diodes in the red sub pixel and the green sub pixel, among the plurality of blue light emitting diodes, and are exposed from the bank; a scattering layer which is disposed on a blue light emitting diode in the blue sub pixel, among the plurality of blue light emitting diodes, and is exposed from the bank; an encapsulation layer which is disposed on the plurality of color conversion layers and the scattering layer and is formed of an organic material expose from the bank; and a light shielding layer which is disposed on the same layer as the encapsulation layer and is disposed on the bank exposed from the encapsulation layer. In the encapsulation layer, an area of a bottom surface may be larger than an area of a top surface, and in the light shielding layer, an area of a bottom surface may be smaller than an area of a top surface.

According to some embodiments, a cross-sectional shape of the encapsulation layer may be a tapered shape, and a cross-sectional shape of the light shielding layer may be a reverse tapered shape.

According to some embodiments, the encapsulation layer may be disposed so as to overlap only the plurality of color conversion layers and the scattering layer, among the plurality of color conversion layers, the scattering layer, and the bank.

According to some embodiments, the encapsulation layer may be hydrophilic.

According to some embodiments, the bank may include a white material, and the light shielding layer may include a black material.

According to some embodiments, the display device may further comprise a plurality of color filters which are disposed so as to correspond respectively to the plurality of color conversion layers and the scattering layer above the encapsulation layer; a black matrix which is disposed between the plurality of color filters on the plurality of color filters; and a second substrate disposed on the plurality of color filters and the black matrix.

According to some embodiments, the plurality of blue light emitting diodes may be disposed so as to overlap the plurality of color conversion layers and the scattering layer, respectively, the encapsulation layer, and the plurality of color filters, respectively, and the bank may be disposed so as to overlap the light shielding layer and the black matrix.

According to some embodiments, a size of the black matrix may be smaller than a size of the light shielding layer.

Although example embodiments of the present disclosure have been described above in detail with reference to the accompanying drawings, the present disclosure is not limited thereto and may be embodied in many different forms without departing from the technical concept of the present disclosure. Therefore, the example embodiments of the present disclosure are provided for illustrative purposes only and are not intended to limit the technical concept of the present disclosure. The scope of the technical concept of the present disclosure is not limited thereto. Therefore, it should be understood that the above-described example embodiments are illustrative in all aspects and do not limit the present disclosure. The protective scope of the present disclosure may be construed based on the following claims and their equivalents, and all the technical concepts in the equivalent scope thereof should be construed as falling within the scope of the present disclosure.

What is claimed is:

1. A display device, comprising:
a first substrate including a plurality of sub pixels;
a plurality of light emitting diodes disposed respectively in the plurality of sub pixels on the first substrate;
a bank which is disposed so as to expose the plurality of light emitting diodes above the plurality of light emitting diodes and has a hydrophobicity;
a plurality of color conversion layers which are disposed respectively on at least two of the plurality of light emitting diodes and are enclosed by the bank;
an encapsulation layer which is disposed on the plurality of color conversion layers and is formed of an organic material; and
a light shielding layer which is disposed on the bank and in a side portion of the encapsulation layer,
wherein an area of the encapsulation layer is downwardly increased, and an area of the light shielding layer is downwardly reduced.

2. The display device according to claim 1, wherein a cross-sectional shape of the encapsulation layer is a tapered shape, and a cross-sectional shape of the light shielding layer is a reverse tapered shape.

3. The display device according to claim 1, wherein the encapsulation layer is disposed so as to overlap only the plurality of color conversion layers, among the plurality of color conversion layers and the bank.

4. The display device according to claim 1, wherein the encapsulation layer is hydrophilic.

5. The display device according to claim 1, wherein the bank includes a white material, and the light shielding layer includes a black material.

6. The display device according to claim 1, further comprising:
a scattering layer, which is disposed on the same layer as the plurality of color conversion layers, on one of the plurality of light emitting diodes other than the at least two of the plurality of light emitting diodes,
wherein the plurality of light emitting diodes are blue light emitting diodes which emit blue light,
wherein the plurality of sub pixels include a red sub pixel, a green sub pixel, and a blue sub pixel,
wherein the plurality of color conversion layers are disposed so as to correspond to the red sub pixel and the green sub pixel, among the plurality of sub pixels, and
wherein the scattering layer is disposed so as to correspond to the blue sub pixel, among the plurality of sub pixels.

7. The display device according to claim 1, further comprising:
a plurality of color filters which are disposed so as to correspond respectively to the plurality of color conversion layers under the encapsulation layer;
a black matrix which is disposed between the plurality of color filters on the plurality of color filters; and
a second substrate disposed on the plurality of color filters and the black matrix.

8. The display device according to claim 7, wherein the at least two of the plurality of light emitting diodes are disposed so as to overlap the plurality of color conversion layers, respectively, the encapsulation layer, and the plurality of color filters, respectively, and
wherein the bank is disposed so as to overlap the light shielding layer and the black matrix.

9. The display device according to claim 7, wherein the light shielding layer and the black matrix are disposed so as to overlap each other, and the black matrix is disposed in an area narrower than the light shielding layer.

10. A display device, comprising:
a first substrate in which a plurality of sub pixels including a red sub pixel, a green sub pixel, and a blue sub pixel are defined;
a plurality of blue light emitting diodes disposed respectively in the plurality of sub pixels on the first substrate and configured to emit blue light;
a bank which is disposed so as to expose the plurality of blue light emitting diodes above the plurality of blue light emitting diodes and has a hydrophobicity;
a plurality of color conversion layers which are disposed respectively on blue light emitting diodes in the red sub pixel and the green sub pixel, among the plurality of blue light emitting diodes, and are exposed from the bank;
a scattering layer which is disposed on a blue light emitting diode in the blue sub pixel, among the plurality of blue light emitting diodes, and is exposed from the bank;
an encapsulation layer which is disposed on the plurality of color conversion layers and the scattering layer exposed from the bank and is formed of an organic material; and
a light shielding layer which is disposed on the same layer as the encapsulation layer and is disposed on the bank exposed from the encapsulation layer,
wherein, in the encapsulation layer, an area of a bottom surface is larger than an area of a top surface, and
wherein, in the light shielding layer, an area of a bottom surface is smaller than an area of a top surface.

11. The display device according to claim 10, wherein a cross-sectional shape of the encapsulation layer is a tapered shape, and a cross-sectional shape of the light shielding layer is a reverse tapered shape.

12. The display device according to claim 10, wherein the encapsulation layer is disposed so as to overlap only the plurality of color conversion layers and the scattering layer, among the plurality of color conversion layers, the scattering layer, and the bank.

13. The display device according to claim 10, wherein the encapsulation layer is hydrophilic.

14. The display device according to claim 10, wherein the bank includes a white material, and the light shielding layer includes a black material.

15. The display device according to claim 10, further comprising:
a plurality of color filters which are disposed so as to correspond respectively to the plurality of color conversion layers and the scattering layer above the encapsulation layer;
a black matrix which is disposed between the plurality of color filters on the plurality of color filters; and
a second substrate disposed on the plurality of color filters and the black matrix.

16. The display device according to claim 15, wherein the plurality of blue light emitting diodes are disposed so as to overlap the plurality of color conversion layers and the scattering layer, respectively, the encapsulation layer, and the plurality of color filters, respectively, and
wherein the bank is disposed so as to overlap the light shielding layer and the black matrix.

17. The display device according to claim 16, wherein a size of the black matrix is smaller than a size of the light shielding layer.
